(19) United States
(12) Patent Application Publication
(10) Pub. No.: US 2026/0206460 A1
(43) Pub. Date: Jul. 16, 2026

(54) COVER MEMBER, DISPLAY APPARATUS, AND ELECTRONIC APPARATUS

(71) Applicant: Samsung Display Co., Ltd., Yongin-si (KR)

(72) Inventors: Hyangshin Jeong, Yongin-si (KR); Sungwoo Kim, Yongin-si (KR); Chanhee Wang, Yongin-si (KR); Kihwan Baek, Yongin-si (KR); Sunho Lee, Yongin-si (KR)

(21) Appl. No.: 19/438,255

(22) Filed: Dec. 31, 2025

(30) Foreign Application Priority Data
Jan. 15, 2025 (KR) 10-2025-0006383

(51) Int. Cl. H10K 59/80; H10K 102/00

(52) U.S. Cl. CPC H10K 59/871; H10K 59/879; H10K 2102/311; H10K 2102/351

(57) ABSTRACT

Provided are a cover member, a display apparatus, and an electronic apparatus. The cover member includes a base layer above the display panel, a coating layer above the base layer, an anti-fingerprint layer above the coating layer, and at least one micro-protrusion on one surface in contact with the anti-fingerprint layer.

### CROSS-REFERENCE TO RELATED APPLICATION

The present application claims priority to, and the benefit of, Korean Patent Application No. 10-2025-0006383, filed on January 15, 2025, in the Korean Intellectual Property Office, the entire disclosure of which is incorporated herein by reference.

### BACKGROUND

### 1. Field

One or more embodiments relate to a cover member, a display apparatus, and an electronic apparatus.

### 2. Description of the Related Art

Electronic devices (electronic apparatuses) based on mobility are widely used. In addition to small electronic devices, such as mobile phones and tablet personal computers (PCs), have recently been widely used as mobile electronic devices.

Such mobile electronic devices include display apparatuses to support various functions and to provide visual information, such as images or videos to users. Recently, as other components for driving display apparatuses have become smaller, the proportion of display apparatuses in electronic devices is gradually increasing, and structures that may be bent to a certain angle from a flat state have been also developed.

### SUMMARY

Generally, a cover member provided in a display apparatus may include a transparent material. If the cover member is too transparent, when foreign substances or scratches are present on a base layer of the cover member, these foreign substances or scratches may cause the visibility of an image on a display panel to degrade, or may be mistaken for a defect in the cover member. One or more embodiments include a cover member that reduces the visibility of foreign substances or scratches present on a base layer by scattering and reflecting a portion of external light incident from outside of the cover member, a display apparatus, and an electronic apparatus.

Additional aspects will be set forth in part in the description that follows and, in part, will be apparent from the description, or may be learned by practice of the presented embodiments of the disclosure.

According to one or more embodiments, a display apparatus includes a display panel, and a cover member including a base layer above the display panel, a coating layer above the base layer, an anti-fingerprint layer above the coating layer, and at least one micro-protrusion on one surface in contact with the anti-fingerprint layer.

The coating layer may include a lower layer above the base layer, an intermediate layer above the lower layer, and an upper layer above the intermediate layer, wherein the upper layer, the intermediate layer, and the lower layer include different respective materials.

A refractive index of one of the lower layer, the intermediate layer, or the upper layer may be different from a refractive index of another one of the lower layer, the intermediate layer, or the upper layer.

A refractive index of the lower layer may be more than about 1.57 and less than about 1.73, and/or wherein a thickness of the lower layer is more than about 80 nm and less than about 123 nm, and/or wherein a refractive index of the intermediate layer is more than about 2.1 and less than about 2.42, wherein a thickness of the intermediate layer is more than about 70 nm and less than about 98 nm, and/or wherein a refractive index of the upper layer is more than about 1.41 and less than about 1.56, and/or wherein a thickness of the upper layer is more than about 68 nm and less than about 90 nm, and/or wherein a filling rate of the upper layer is more than about 40% and less than about 160%, and/or wherein the coating layer has an average reflectance of more than about 8.5% and less than about 12% when irradiated with light with a wavelength of more than about 520 nm and less than about 580 nm, and/or wherein the coating layer has an average transmittance of more than about 88% and less than about 91.5% when irradiated with light with a wavelength of more than about 520 nm and less than about 580 nm, and/or wherein a thickness of the anti-fingerprint layer is more than about 10 nm and less than about 40 nm.

The lower layer may include aluminum oxide.

The intermediate layer may include titanium oxide.

The upper layer may include silicon dioxide.

A refractive index of the upper layer may be greater than a refractive index of the anti-fingerprint layer.

According to one or more embodiments, an electronic apparatus includes a display apparatus, wherein the display apparatus includes a display panel, and a cover member including a base layer above the display panel, a coating layer above the base layer, an anti-fingerprint layer above the coating layer, and at least one micro-protrusion on one surface in contact with the anti-fingerprint layer.

The coating layer may include a lower layer above the base layer, an intermediate layer above the lower layer, and an upper layer above the intermediate layer, wherein the upper layer, the intermediate layer, and the lower layer include different respective materials.

A refractive index of one of the lower layer, the intermediate layer, or the upper layer may be different from a refractive index of another one of the lower layer, the intermediate layer, or the upper layer.

A refractive index of the lower layer may be more than about 1.57 and less than about 1.73, and/or wherein a refractive index of the intermediate layer is more than about 2.1 and less than about 2.42, and/or wherein a refractive index of the upper layer is more than about 1.41 and less than about 1.56, and/or wherein a refractive index of the upper layer is greater than a refractive index of the anti-fingerprint layer.

According to one or more embodiments, a cover member includes a base layer above a display panel, a coating layer above the base layer, an anti-fingerprint layer above the coating layer, and at least one micro-protrusion on one surface in contact with the anti-fingerprint layer.

The coating layer may include a lower layer above the base layer, an intermediate layer above the lower layer, and an upper layer above the intermediate layer, wherein the upper layer, the intermediate layer, and the lower layer include different respective materials.

A refractive index of one of the lower layer, the intermediate layer, or the upper layer may be different from a refractive index of another one of the lower layer, the intermediate layer, or the upper layer.

A refractive index of the lower layer may be more than about 1.57 and less than about 1.73, and/or wherein a thickness of the lower layer is more than about 80 nm and less than about 123 nm, and/or wherein a thickness of the intermediate layer is more than about 70 nm and less than about 98 nm, and/or wherein a refractive index of the intermediate layer is more than about 2.1 and less than about 2.42, and/or wherein a filling rate of the upper layer is more than about 40% and less than about 140%, and/or wherein a refractive index of the upper layer is more than about 1.41 and less than about 1.56, and/or wherein a thickness of the upper layer is more than about 68 nm and less than about 90 nm, and/or wherein the coating layer has an average reflectance of more than about 8.5% and less than about 12% when irradiated with light with a wavelength of more than about 520 nm and less than about 580 nm, and/or wherein the coating layer has an average transmittance of more than about 88% and less than about 91.5% when irradiated with light with a wavelength of more than about 520 nm and less than about 580 nm, and/or wherein a thickness of the anti-fingerprint layer is more than about 9 nm and less than about 40 nm.

The lower layer may include aluminum oxide.

The intermediate layer may include titanium oxide.

The upper layer may include silicon dioxide.

A refractive index of the upper layer may be greater than a refractive index of the anti-fingerprint layer.

Aspects other than those described above will become apparent from the following drawings, claims, and detailed description of the disclosure.

### BRIEF DESCRIPTION OF THE DRAWINGS

The above and other aspects of embodiments of the disclosure will be more apparent from the following description taken in conjunction with the accompanying drawings, in which:

FIG. 1 is a block diagram of an electronic apparatus according to one or more embodiments;

FIGS. 2 to 4 are schematic views of electronic apparatuses according to various embodiments;

FIG. 5 is a perspective view schematically illustrating an electronic apparatus according to one or more embodiments;

FIG. 6 is an exploded perspective view schematically illustrating the electronic apparatus of FIG. 5;

FIG. 7 is a block diagram schematically illustrating the electronic apparatus of FIG. 5;

FIG. 8A is a plan view schematically illustrating a portion of a display apparatus according to one or more embodiments;

FIG. 8B is a side view schematically illustrating a portion of the display apparatus of FIG. 8A;

FIG. 9 is a plan view schematically illustrating a portion of a display apparatus according to one or more embodiments;

FIG. 10 is an equivalent circuit diagram of one sub-pixel arranged in a display area of a display panel of FIG. 8A;

FIG. 11 is a cross-sectional view schematically illustrating a portion of the display area of the display panel of FIG. 8A;

FIG. 12 is a cross-sectional view schematically illustrating a cover member according to one or more embodiments;

FIG. 13 is an enlarged cross-sectional view of a portion C of FIG. 12;

FIG. 14 is a cross-sectional view schematically illustrating a cover member according to one or more other embodiments; and

FIG. 15 is an enlarged cross-sectional view of a portion D of FIG. 14.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature’s relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When "C to D" is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer, or section described below could be termed a second element, component, region, layer, or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/- 5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ± 30%, 20%, 10%, 5% of the stated value. Further, the use of “may” when describing embodiments of the present disclosure refers to “one or more embodiments of the present disclosure.” Furthermore, the expression “being the same” may mean “being substantially the same.” In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

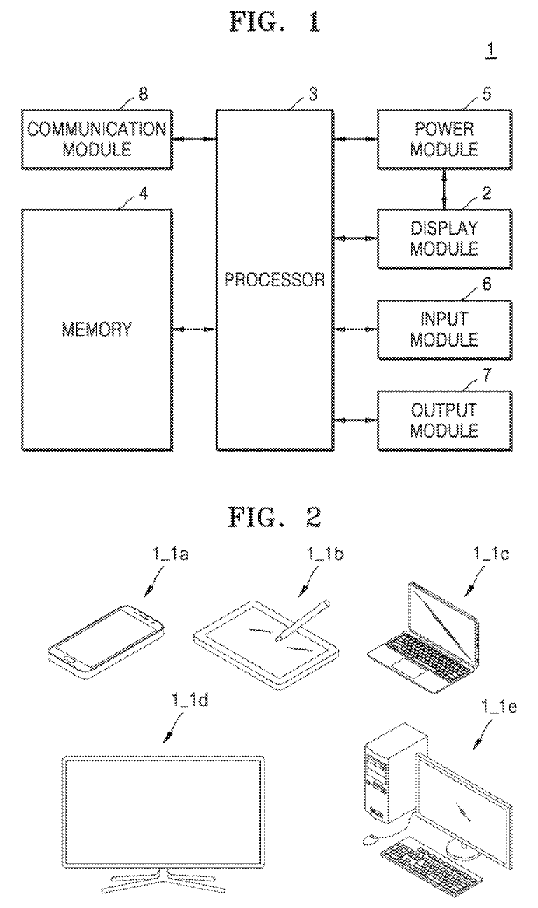

FIG. 1 is a block diagram of an electronic apparatus according to one or more embodiments.

Referring to FIG. 1, an electronic apparatus 1 according to one or more embodiments may include a display module 2 including a display apparatus, a processor 3, a memory 4, and a power module 5.

The processor 3 may include at least one of a central processing unit (CPU), an application processor (AP), a graphics processing unit (GPU), a communication processor (CP), an image signal processor (ISP), or a controller. In one or more embodiments, the processor 3 may be provided as two or more separate units from a functional or structural perspective. For example, the processor 3 may include a main processor in the form of a first driving chip including a CPU and an auxiliary processor in the form of a second driving chip including a controller, wherein the auxiliary processor receives an image signal from the main processor and processes the image signal to satisfy interface specifications of the display module 2.

The memory 4 may include at least one of non-volatile memory or volatile memory. The memory 4 may store data information required to operate the processor 3 or the display module 2. When the processor 3 executes an application stored in the memory 4, an image data signal and/or an input control signal may be transmitted to the display module 2, and the display module 2 may process the received signal and output image information via a display screen.

The power module 5 may include a power supply module, such as a power adapter or a battery apparatus, and a power conversion module that converts power supplied by the power supply module and generates power required to operate the electronic apparatus 1. Power conversion by the power conversion module may include direct current (DC)-DC conversion, alternating current (AC)-DC conversion, and DC-AC conversion, but is not limited thereto.

The electronic apparatus 1 may further include an input module 6, a non-image output module 7, and/or a communication module 8.

The input module 6 may provide input information to the processor 3 and/or the display module 2. The input module 6 may include a physical button, a keyboard, a microphone, and various sensor modules. Examples of a sensor module may include not only a touch sensor, a pressure sensor, a distance sensor, a location sensor, a digitizer, a motion recognition sensor, a camera sensor, a light-receiving sensor, a photoelectric conversion sensor, and a temperature sensor, but also a biometric sensor, such as a blood pressure sensor, a blood glucose sensor, an electrocardiogram sensor, and a heart rate sensor.

The non-image output module 7 may receive information other than an image received from the processor 3 and provide the information to a user. Examples of the non-image output module 7 may be an audio module, a haptic module, and a light-emitting module, and may include other functional modules (for example, a cooling module of a refrigerator) that are unique to the electronic apparatus 1.

The communication module 8 is responsible for transmission and reception of information between the electronic apparatus 1 and an external apparatus, and may include a receiver and a transmitter. The communication module 8 may include various wireless communication modules, such as a mobile communication module, a an wireless-fidelity (Wi‑Fi^{®}) module, or a Bluetooth^{®} module (Wi‑Fi^{®} being a registered trademark of the non-profit Wi-Fi Alliance, and Bluetooth^{®} being a registered trademark of Bluetooth Sig, Inc., Kirkland, WA), or various wired communication modules.

At least one of the components of the electronic apparatus 1 may be included in the display apparatus according to the above-described embodiments. In addition, some individual modules functionally included within one module may be included in the display apparatus, and other individual modules may be provided separately from the display apparatus. For example, the display apparatus may include the display module 2, and the processor 3, the memory 4, and the power module 5 may be provided in the form of other apparatuses within the electronic apparatus 1 rather than the display apparatus. In another example, the power module 5 may be provided within the display apparatus and may supply power to the processor 3 and the memory 4, which are provided within the electronic apparatus 1 rather than the display apparatus, and these examples are not limited thereto.

FIGS. 2 to 4 are schematic views of electronic apparatuses according to various embodiments. FIGS. 2 to 4 show examples of various electronic apparatuses to which a display apparatus according to one or more embodiments is applied.

FIG. 2 shows, as examples of an electronic apparatus, a smartphone 1_1a, a tablet personal computer (PC) 1_1b, a laptop 1_1c, a television(TV) 1_1d, and a desk monitor 1_1e.

The smartphone 1_1a may include an input module, such as a touch sensor, and a communication module, in addition to the display module 2 (see FIG. 1). The smartphone 1_1a may process information received via the communication module or other input modules and display the information via the display module of the display apparatus.

Similar to the smartphone 1_1a, the tablet PC 1_1b, the laptop 1_1c, the TV 1_1d, and the desk monitor 1_1e may include a display module and an input module, and in some cases, may further include a communication module.

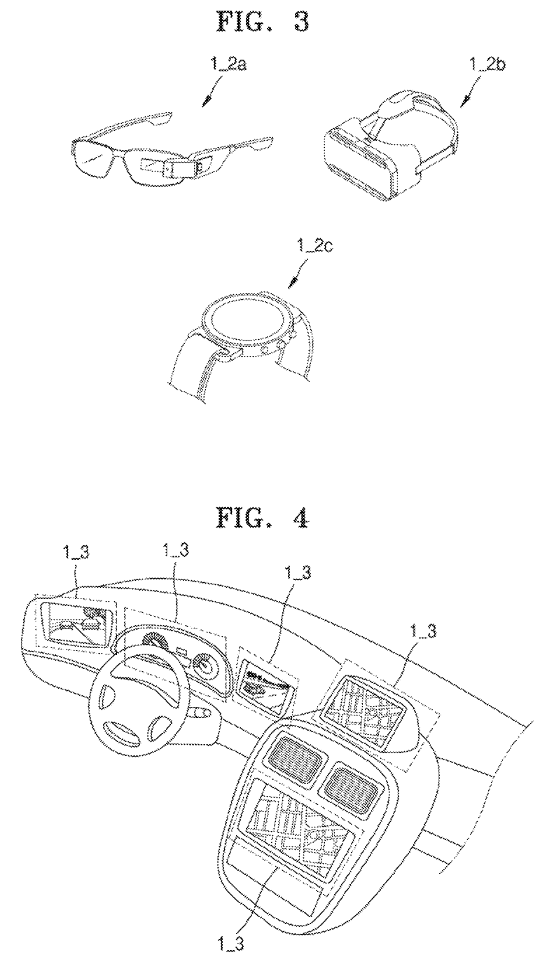

FIG. 3 shows a case where an electronic apparatus including a display module is applied to a wearable electronic apparatus. The wearable electronic apparatus may include smart glasses 1_2a, a head-mounted display 1_2b, and a smart watch 1_2c.

The smart glasses 1_2a and the head-mounted display 1_2b may include a display module that displays a display image, and a reflector that reflects a displayed display screen and provides it to a user's eyes, thereby providing a virtual reality or augmented reality screen to the user.

The smart watch 1_2c may include a biometric sensor as an input apparatus, and may provide biometric information recognized by a biometric sensor to a user via a display module.

FIG. 4 shows a case where an electronic apparatus including a display module is applied to a vehicle. For example, an electronic apparatus 1_3 may be applied to an instrument panel of a vehicle or a center fascia, or may be applied to a center information display (CID) arranged on/in the dashboard of a vehicle or a room mirror display in place of side-view mirrors.

In one or more embodiments, an electronic apparatus to which a display apparatus is applied according to one or more embodiments may include not only apparatuses focused on screen display, such as billboards, electronic billboards, and game device, but also various home appliances that display information via a display module, such as refrigerators, washing machines, dryers, air conditioners, and robot vacuums. In addition, when a display module has a function of transmitting light, the display module may be applied to an electronic apparatus, such as a smart window or a transparent display apparatus that displays a background and a display image together. The types of electronic apparatuses according to one or more embodiments are not limited to the examples provided above, and the application of other various electronic apparatuses that are not provided as examples is also possible.

Hereinafter, for convenience of explanation, a case where the electronic apparatus 1 is a smartphone is mainly described in detail.

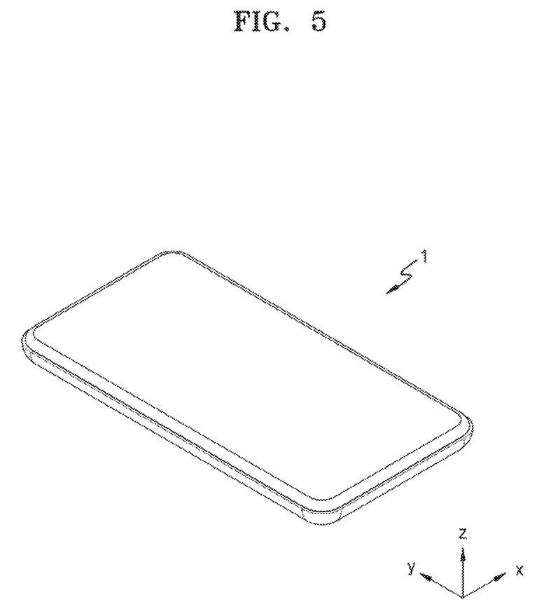

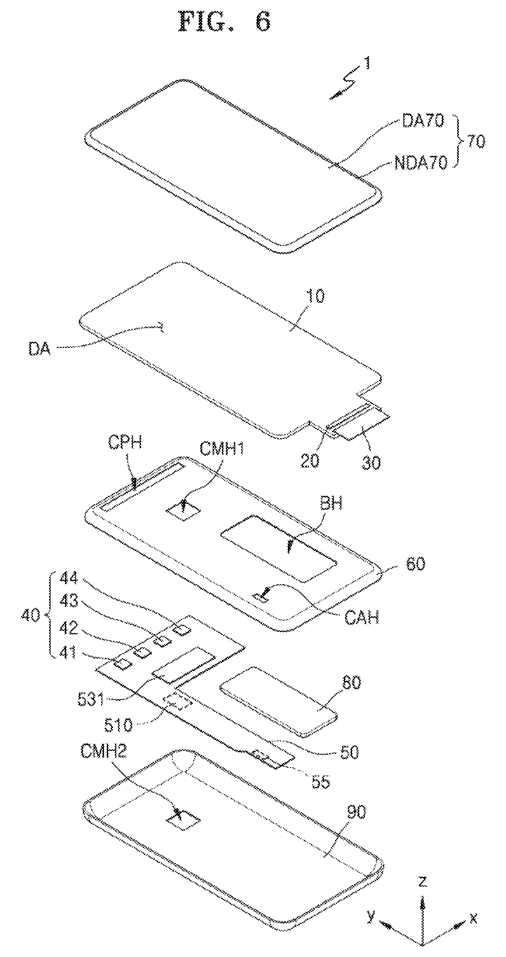

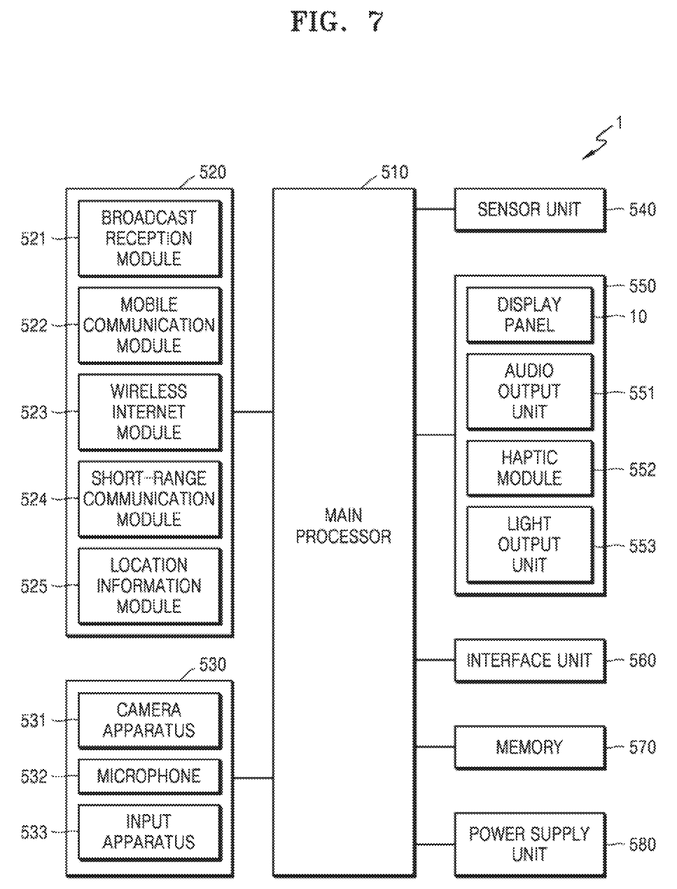

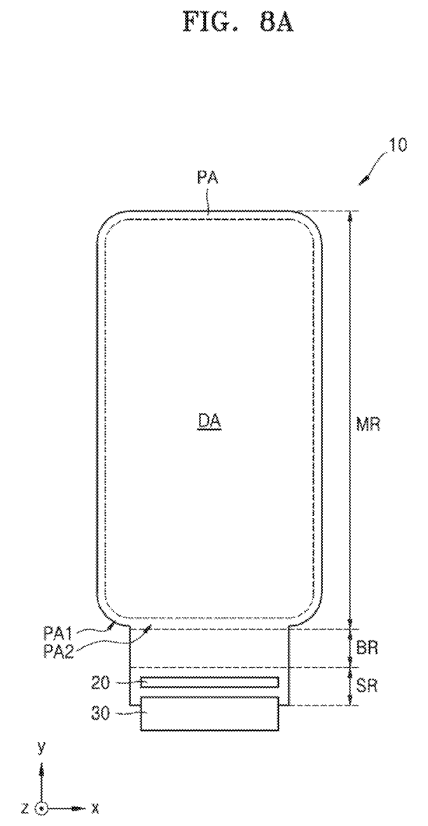

FIG. 5 is a perspective view schematically illustrating an electronic apparatus according to one or more embodiments. FIG. 6 is an exploded perspective view schematically illustrating the electronic apparatus of FIG. 5. FIG. 7 is a block diagram schematically illustrating the electronic apparatus of FIG. 5.

Referring to FIGS. 5 to 7, the electronic apparatus 1 may include a display apparatus including a cover member 70, a display panel 10, a data driver 20, and a display circuit board 30, components 40, a bracket 60, a main circuit board 50, a battery 80, and/or a lower cover 90.

In the present specification, "left," "right," "above," and "under" in a plan view indicate directions when the display panel 10 is viewed in a direction perpendicular to a top surface the display panel 10. For example, "left" refers to a -x direction, "right" refers to a +x direction, "above" refers to a +y direction, and "under" refers to a -y direction.

The electronic apparatus 1 may have an approximately rectangular shape in a plan view. For example, as shown in FIG. 5, the electronic apparatus 1 may have an approximately rectangular shape with a short side in an x-axis direction and a long side in a y-axis direction in an xy plane. In this case, a corner where the short side in the x-axis direction and the long side in the y-axis direction meet may form a right angle, and may have a rounded shape with a certain curvature. In a plan view, the electronic apparatus 1 may have a polygonal shape other than a rectangular shape, or may have an elliptical shape or an irregular shape.

The cover member 70 may be arranged above the display panel 10 to cover a top surface of the display panel 10. The cover member 70 may function to protect the top surface of the display panel 10.

The cover member 70 may include a transmissive cover portion DA70 corresponding to the display panel 10, and a light-blocking cover portion NDA70 surrounding the transmissive cover portion DA70. The light-blocking cover portion NDA70 may include an opaque material (for example, a colored opaque material) that blocks light. The light-blocking cover portion NDA70 may include a pattern that is visible to a user when an image is not displayed.

The display panel 10 may be arranged under the cover member 70. The display panel 10 may overlap the transmissive cover portion DA70 of the cover member 70. The display panel 10 may include a display area DA. The display area DA is where an image is displayed, and the display area DA may include an area (referred to as a component area) that transmits light emitted from the components 40 arranged under the display panel 10. The components 40 may include a sensor or camera that uses visible light, infrared rays, or sound.

The display panel 10 may be a light-emitting display panel including a light-emitting diode. The light-emitting diode may be an organic light-emitting diode including an organic emission layer, or may be an inorganic light-emitting diode including an inorganic material. The inorganic light-emitting diode may include a PN junction diode including inorganic semiconductor-based materials. When a voltage is applied to a PN junction diode in a forward direction, holes and electrons are injected, and energy generated due to recombination of the holes and the electrons is converted into light energy to emit light of a certain color. The inorganic light-emitting diode may have a width of several micrometers to hundreds of micrometers. The inorganic light-emitting diode may be referred to as a micro light-emitting diode (LED).

The display panel 10 may be a rigid display panel that is rigid, and thus is not easily bent, or may be a flexible display panel that is flexible, and thus may be easily bent, folded, or rolled. For example, the display panel 10 may be a foldable display panel, a curved display panel with a bent display surface, a bent display panel with a bent area other than a display surface, a rollable display panel, or a stretchable display panel.

The display panel 10 may be a transparent display panel that, due to being transparent, allows an object or background under a bottom surface of the display panel 10 to be visible from the top surface of the display panel 10. Alternatively, the display panel 10 may be a reflective display panel capable of reflecting an object or background from the top surface of the display panel 10.

The data driver 20 may be mounted on the display panel 10 in the form of an integrated circuit (IC). The disclosure is not limited thereto, and for example, the data driver 20 may be mounted on the display circuit board 30.

The display circuit board 30 may be attached to one side of the display panel 10. The display circuit board 30 may be a flexible printed circuit board (FPCB) that may be bent, a rigid printed circuit board (PCB) that is hard and is not easily bent, or a composite printed circuit board including both a rigid PCB and an FPCB. A touch sensor driver (e.g., a touch sensor-driving unit) may be mounted on the display circuit board 30. The touch sensor driver may be formed as an IC. The touch sensor driver may be electrically connected to touch electrodes of a touch screen layer of the display panel 10 via the display circuit board 30.

The touch screen layer of the display panel 10 may sense a user's touch input, by using at least one of various touch methods, such as a resistive film method or an electrostatic capacitance method. When the touch screen layer of the display panel 10 senses a user's touch input by using an electrostatic capacitance method, the touch sensor driver may apply driving signals to driving electrodes among the touch electrodes, and sense voltage charges of mutual electrostatic capacitance (referred to as "mutual capacitance") between the driving electrodes and sensing electrodes via the sensing electrodes among the touch electrodes, to thereby determine whether the user has touched the touch screen layer.

The user's touch may include contact touch and proximity touch. The contact touch refers to direct contact of an object, such as the user's finger or a pen, with the cover member 70 arranged on the touch screen layer. The proximity touch refers to a situation where an object, such as the user's finger or a pen, is positioned closely on, but not in direct contact with, the cover member 70, for example by hovering. The touch sensor driver may transmit sensor data to a main processor 510 according to the sensed voltages, and the main processor 510 may calculate touch coordinates where the touch input has occurred, by analyzing the sensor data.

A controller for supplying driving voltages for driving sub-pixels, a gate driver, and/or the data driver 20 of the display panel 10 may be arranged on the display circuit board 30.

The bracket 60 for supporting the display panel 10 may be arranged under the display panel 10. The bracket 60 may include plastic, metal, or both plastic and metal. The bracket 60 may include a first camera hole CMH1 into which a camera apparatus 531 is inserted, a battery hole BH where the battery 80 is arranged, a cable hole CAH through which a cable connected to the display circuit board 30 passes, and a component hole CPH corresponding to the components 40. The component hole CPH may overlap the components 40 of the main circuit board 50 when viewed in a third direction (a z-axis direction). For reference, the display area DA of the display panel 10 may overlap the components 40 of the main circuit board 50 when viewed in the third direction (the z-axis direction). As suitable, the bracket 60 may not have the component hole CPH.

The components 40 included in the electronic apparatus 1 may include a first component 41, a second component 42, a third component 43, and a fourth component 44, which overlap the display panel 10. Each of the first component 41, the second component 42, the third component 43, and the fourth component 44 may include at least one of a proximity sensor, an illumination sensor, an iris sensor, a facial recognition sensor, or a camera (or an image sensor). The proximity sensor using infrared rays may detect an object positioned close to a top surface of the electronic apparatus 1, and the illumination sensor may sense the brightness of light incident on the top surface of the electronic apparatus 1. In addition, the iris sensor may capture an image of an iris of a person positioned on the top surface of the electronic apparatus 1, and the camera may obtain image data for an object arranged on the top surface of the electronic apparatus 1. The components 40 are not limited to the proximity sensor, the illumination sensor, the iris sensor, the facial recognition sensor, and/or the camera, and may include other sensors.

The main circuit board 50 and the battery 80 may be arranged under the bracket 60. The main circuit board 50 may be a rigid printed circuit board or an FPCB.

The main circuit board 50 may include the main processor 510, the camera apparatus 531, a main connector 55, and the components 40. The main processor 510 may be formed as an IC. As suitable, the electronic apparatus 1 may include not only the camera apparatus 531 arranged on a top surface of the main circuit board 50, but also may include a camera apparatus arranged on a bottom surface of the main circuit board 50. Each of the main processor 510 and the main connector 55 may be arranged on one of the top surface or the bottom surface of the main circuit board 50. The main circuit board 50 may be electrically connected to the display circuit board 30 via the main connector 55.

The main processor 510 may control all functions of the electronic apparatus 1. For example, the main processor 510 may output digital video data to the data driver 20 via the display circuit board 30 so that the display panel 10 displays an image. The main processor 510 may receive sensing data from the touch sensor driver. The main processor 510 may determine, according to the sensing data, whether a user has touched the touch screen layer, and may perform an operation corresponding to the user's direct touch or proximity touch. The main processor 510 may be an AP, a CPU, or a system chip, each including an IC.

The camera apparatus 531 may process an image frame of a still image or moving image obtained by an image sensor in a camera mode and output the processed image frame to the main processor 510. The camera apparatus 531 may include at least one of a camera sensor (for example, a charge-coupled device (CCD) or a complementary metal-oxide-semiconductor (CMOS)), a photo sensor (or an image sensor), or a laser sensor.

A cable passing through the cable hole CAH in the bracket 60 may be connected to the main connector 55, and the main circuit board 50 may be electrically connected to the display circuit board 30 via the cable.

The electronic apparatus 1 may be represented by a block diagram as illustrated in FIG. 7. The electronic apparatus 1 may include a wireless communication unit 520, an input unit 530, a sensor unit 540, an output unit 550, an interface unit 560, a memory 570, and/or a power supply unit 580 as shown in FIG. 7, in addition to the main processor 510.

The wireless communication unit 520 may include at least one of a broadcast reception module 521, a mobile communication module 522, a wireless Internet module 523, a short-range communication module 524, or a location information module 525.

The broadcast reception module 521 receives a broadcast signal and/or broadcast-related information from an external broadcast management server via a broadcast channel. The broadcast channel may include a satellite channel and a terrestrial channel.

The mobile communication module 522 transmits and receive a wireless signal to or from at least one of a base station, an external terminal, or a server on a mobile communication network constructed according to technical standards or communication methods for mobile communication (for example, global system for mobile communication (GSM), code-division multi access (CDMA), code-division multi access 2000 (CDMA2000), enhanced voice-data optimized or enhanced voice-data only (EV-DO), wideband CDMA (WCDMA), high-speed downlink packet access (HSDPA), high-speed uplink packet access (HSUPA), long-term evolution (LTE), long- term evolution advanced (LTE-A), etc.). The wireless signal may include various types of data according to transmission and reception of a voice call signal, a video call signal, or a text/multimedia message.

The wireless Internet module 523 refers to a module for wireless Internet access. The wireless Internet module 523 may be configured to transmit and receive a wireless signal in a communication network according to wireless Internet technologies. The wireless Internet technologies may be, for example, wireless LAN (WLAN), wireless-fidelity (Wi‑Fi^{®}) (Wi‑Fi^{®} being a registered trademark of the non-profit Wi-Fi Alliance), Wi-Fi Direct^{TM} (Wi-Fi Direct^{TM} being a registered trademark of the non-profit Wi-Fi Alliance), and/or digital living network alliance (DLNA).

The short-range communication module 524 is for short-range communication and may support the short-range communication by using at least one of Bluetooth^{®} (Bluetooth^{®} being a registered trademark of Bluetooth Sig, Inc., Kirkland, WA), radio frequency identification (RFID), infrared data association (IrDA), ultra wideband (UWB), Zigbee^{®} (Zigbee^{®} being a registered trademark of CONNECTIVITY STANDARDS ALLIANCE, Davis, CA), near-field communication (NFC), Wi‑Fi^{®} (Wi‑Fi^{®} being a registered trademark of the non-profit Wi-Fi Alliance), Wi-Fi Direct^{TM} (Wi-Fi Direct^{TM} being a registered trademark of the non-profit Wi-Fi Alliance), and wireless universal serial bus (wireless USB) technologies. The short-range communication module 524 may support wireless communication between the electronic apparatus 1 and a wireless communication system, between the electronic apparatus 1 and another electronic apparatus, or between the electronic apparatus 1 and a network where another electronic apparatus (or an external server) is located via wireless area networks. The wireless area networks may be wireless personal area networks. The other electronic apparatus may be a wearable device capable of exchanging data with (or capable of being linked to) the electronic apparatus 1.

The location information module 525 is a module for obtaining a location of the electronic apparatus 1 and may include a global positioning system (GPS) module or a Wi‑Fi^{®} module (Wi‑Fi^{®} being a registered trademark of the non-profit Wi-Fi Alliance).

The input unit 530 may include an image input unit, such as the camera apparatus 531 for inputting an image signal, an audio input unit, such as a microphone 532 for inputting an audio signal, and an input apparatus 533 for receiving information from a user. The camera apparatus 531 processes an image frame of a still image or moving image obtained by an image sensor in a video call mode or shooting mode. The processed image frame may be displayed on the display panel 10 or may be stored in the memory 570. The microphone 532 processes an external audio signal into electrical voice data. The processed electrical voice data may be utilized in various ways according to a function (or an application) being executed in the electronic apparatus 1.

The main processor 510 may control operation of the electronic apparatus 1 to correspond to information input via the input apparatus 533. The input apparatus 533 may include a touch input means or a mechanical input means, such as a button, a dome switch, a jog wheel, a jog switch, etc., which is located on a rear or side surface of the electronic apparatus 1. The touch input means may include the touch screen layer of the display panel 10.

The sensor unit 540 may include one or more sensors that sense at least one of information inside the electronic apparatus 1, information about an environment surrounding the electronic apparatus 1, or user information, and generate a corresponding sensing signal. The main processor 510 may control-driving or operation of the electronic apparatus 1 based on the sensing signal or may perform data processing, a function, or an operation, each being related to an application installed in the electronic apparatus 1. The sensor unit 540 may be a proximity sensor, an illumination sensor, or a facial recognition sensor, as described above in relation to the components 40. The sensor unit 540 may include an acceleration sensor, a magnetic sensor, a gravity sensor (G-sensor), a gyroscope sensor, a motion sensor, an RGB sensor, an infrared (IR) sensor, a fingerprint scan sensor, an ultrasonic sensor, an optical sensor, and/or a battery gauge. In addition, the sensor unit 540 may include an environment sensor or a chemical sensor. The environment sensor may be, for example, a barometer, a hygrometer, a thermometer, a radiation detection sensor, a heat detection sensor, and/or a gas detection sensor. The chemical sensor may be, for example, an electronic nose, a healthcare sensor, and/or a biometric sensor.

The output unit 550 is for generating output related to a visual, auditory, or tactile sense, and may include at least one of the display panel 10, an audio output unit 551, a haptic module 552, or a light output unit 553.

The display panel 10 displays (outputs) information processed by the electronic apparatus 1. For example, the display panel 10 may display execution screen information of an application running on the electronic apparatus 1, display a user interface (UI) according to the execution screen information, or display graphical user interface (GUI) information. The display panel 10 may include a display layer that displays an image, and a touch screen layer that senses a user's touch input. Accordingly, the display panel 10 may function as the input apparatus 533 that provides an input interface between the electronic apparatus 1 and the user, and at the same time, function as the output unit 550 that provides an output interface between the electronic apparatus 1 and the user.

The audio output unit 551 may output audio data received from the wireless communication unit 520, or audio data stored in the memory 570, in a call signal reception mode, call mode, recording mode, voice recognition mode, and/or broadcast reception mode. The audio output unit 551 may also output an audio signal related to a function (for example, call signal reception sound, message reception sound, etc.) performed in the electronic apparatus 1. The audio output unit 551 may include a receiver and a speaker. At least one of the receiver or the speaker may be an audio generation apparatus that is attached to a lower portion of the display panel 10 and outputs audio by vibrating the display panel 10. The audio generation apparatus may be a piezoelectric element or a piezoelectric actuator, which each contracts and expands according to an electrical signal, or may be an exciter that generates magnetic force by using a voice coil to vibrate the display panel 10.

The haptic module 552 generates various tactile effects that may be felt by a user. The haptic module 552 may provide vibration to a user as a tactile effect. The haptic module 552 may not only transfer a tactile effect via direct contact, but may also be implemented such that a user may feel a tactile effect via a muscle sense, such as a finger or an arm.

The light output unit 553 outputs a signal for notifying occurrence of an event by using light from a light source. Examples of the event that occurs in the electronic apparatus 1 may include message reception, call signal reception, missed calls, alarms, schedule notification, email reception, and/or information reception via an application. The signal output by the light output unit 553 is generated by the light source emitting monochromatic or multi-colored light from either a front surface or a rear surface of the electronic apparatus 1. The signal output may be terminated when the electronic apparatus 1 detects a user's event acknowledgement.

The interface unit 560 serves as a conduit for various types of external devices connected to the electronic apparatus 1. The interface unit 560 may include at least one of a wired/wireless headset port, an external charger port, a wired/wireless data port, a memory card port, a port for connecting an apparatus equipped with an identification module, an audio input/output (I/O) port, a video I/O port, or an earphone port. When an external device is connected to the interface unit 560, the electronic apparatus 1 may perform appropriate control related to the connected external device.

The memory 570 stores data that supports various functions of the electronic apparatus 1. The memory 570 may store a plurality of application programs running on the electronic apparatus 1, data for the operation of the electronic apparatus 1, and/or commands. At least some of the plurality of application programs may be downloaded from an external server via wireless communication. The memory 570 may store an application for the operation of the main processor 510, and may also temporarily store input/output data, for example, data, such as a phonebook, a message, a still image, and/or a moving image. In addition, the memory 570 may store haptic data for various patterns of vibration provided to the haptic module 552, and audio data relating to a variety of audio provided to the audio output unit 551.

The memory 570 may include at least one type of storage medium among a flash memory type, a hard disk type, a solid state disk (SSD) type, a multimedia card micro type, a card type memory (for example, SD or XD memory), random access memory (RAM), static RAM (SRAM), read-only memory (ROM), electrically erasable programmable ROM (EEPROM), programmable ROM (PROM), a magnetic memory, a magnetic disk, or an optical disk.

The power supply unit 580 receives external or internal power and supplies the power to each of components included in the electronic apparatus 1, under control by the main processor 510. The power supply unit 580 may include the battery 80. In addition, the power supply unit 580 may include a connection port, and the connection port may be an example of the interface unit 560 to which an external charger that supplies power for charging a battery is electrically connected. Alternatively, the power supply unit 580 may allow the battery 80 to be charged wirelessly. The battery 80 may be arranged not to overlap the main circuit board 50 in the third direction (a z direction). The battery 80 may overlap the battery hole BH in the bracket 60.

The lower cover 90 may form an exterior of the electronic apparatus 1, and may have an opening exposing a portion of the display panel 10. The lower cover 90 has a shape in which a surface corresponding to the display panel 10 is open, and may be fastened to the display panel 10. The lower cover 90 may be arranged at an opposite side to the cover member 70 with the display panel 10 therebetween. The lower cover 90 may be arranged under the main circuit board 50 and the battery 80. The lower cover 90 may be fastened and fixed to the bracket 60. The lower cover 90 may form an exterior of a bottom surface of the electronic apparatus 1. The lower cover 90 may include plastic, metal, or both plastic and metal.

A second camera hole CMH2 through which a bottom surface of the camera apparatus 531 is exposed may be formed in the lower cover 90. A position of the camera apparatus 531 and positions of the first camera hole CMH1 and the second camera hole CMH2 corresponding to the camera apparatus 531 may not be limited to those shown in FIG. 6 and may be changed in various ways.

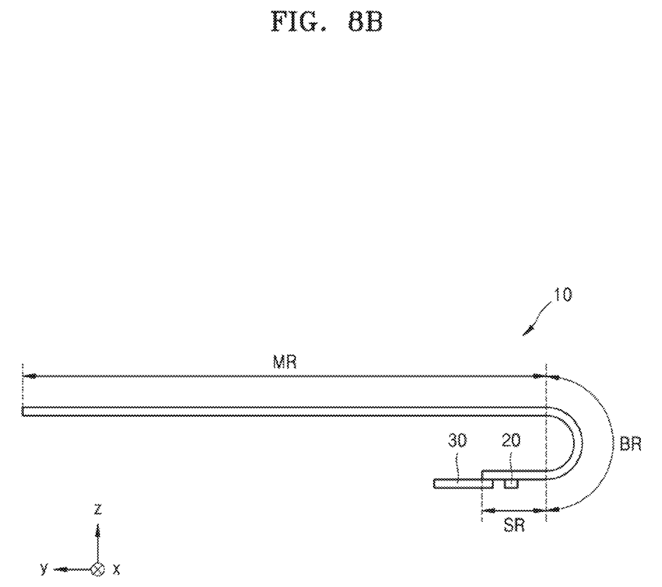

FIG. 8A is a plan view schematically illustrating a portion of a display apparatus according to one or more embodiments. FIG. 8B is a side view schematically illustrating a portion of the display apparatus of FIG. 8A. The electronic apparatus 1 described above with reference to FIGS. 5 to 7 may include the display panel 10 as shown in FIGS. 8A and 8B.

Referring to FIGS. 8A and 8B, the display panel 10 may include the display area DA and a peripheral area PA outside the display area DA. The display area DA is a portion that displays an image and is where a plurality of sub-pixels may be arranged. The display area DA may have various shapes, such as a circle, an ellipse, a polygon, and other specific shape. FIG. 8A illustrates that the display area DA has an approximately rectangular shape with rounded corners.

The peripheral area PA may be arranged outside the display area DA. The peripheral area PA may include a first peripheral area PA1 arranged to surround at least a portion of the display area DA, and a second peripheral area PA2 arranged at a bottom end of the display area DA and extending in a first direction (the x-axis direction). The width of the second peripheral area PA2 in the first direction (the x-axis direction) may be less than the width of the display area DA in the first direction (x-axis direction). This structure makes it easier to bend at least a portion of the second peripheral area PA2.

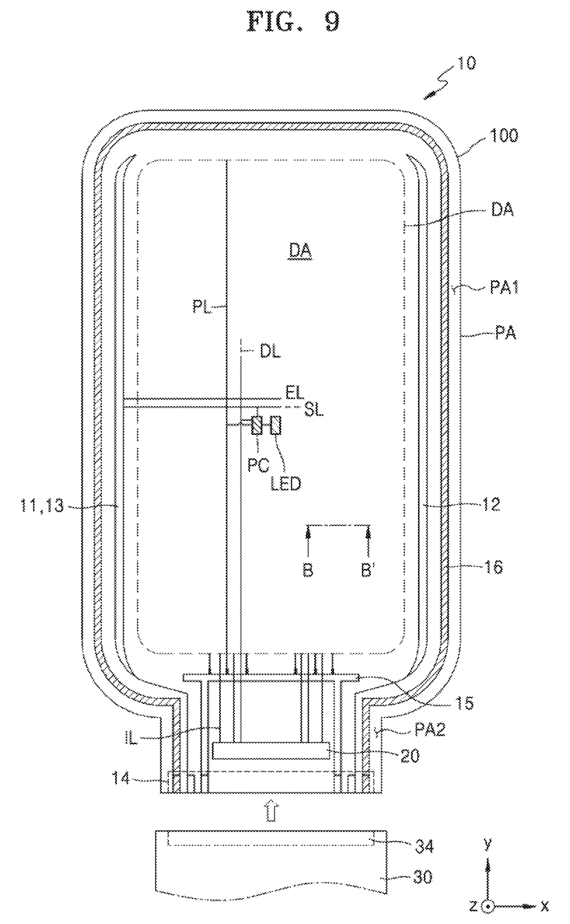

The planar shape of the display panel 10 shown in FIG. 8A may be substantially the same as the planar shape of a substrate 100 (see FIG. 9) included in the display panel 10. When the display panel 10 includes the display area DA, and the peripheral area PA outside the display area DA, it means that the substrate 100 includes the display area DA, and the peripheral area PA outside the display area DA. Hereinafter, for convenience, it is described that the substrate 100 has the display area DA and the peripheral area PA.

The display panel 10 may include a main area MR, a bending area BR outside the main area MR, and a sub-area SR spaced apart from the main area MR with the bending area BR therebetween. The main area MR may be arranged on one side of the bending area BR, and the sub-area SR may be arranged on the other side of the bending area BR. The display panel 10 may be bent in the bending area BR as shown in FIG. 8B, and when viewed in the third direction (the z-axis direction), at least a portion of the sub-area SR may overlap the main area MR. FIG. 8B illustrates that the display panel 10 is bent, but the disclosure is not limited thereto. For example, the display panel 10 may be a foldable display panel, and in this case, the display panel 10 may be bent within the display area DA around a bending axis that crosses the display area DA. If suitable, the display panel 10 may not be bent. The sub-area SR may be a non-display area.

The data driver 20 may be arranged in the sub-area SR of the display panel 10. The data driver 20 may be arranged on the display panel 10 in the form of an IC. For example, the data driver 20 may be a data-driving IC that is configured to generate a data signal.

The display circuit board 30 may be attached to an end portion of the sub-area SR of the display panel 10. The display circuit board 30 may be electrically connected to the data driver 20, etc. via a pad of the sub-area SR of the display panel 10.

FIG. 9 is a plan view schematically illustrating a portion of a display apparatus according to one or more embodiments.

Referring to FIG. 9, the display panel 10 may include the substrate 100. Various components of the display panel 10 may be arranged on the substrate 100.

The substrate 100 may include glass, ceramic, metal, or polymer resin. The substrate 100 may include, for example, polymer resin, such as polyethersulfone, polyacrylate, polyetherimide, polyethylene naphthalate, polyethylene terephthalate, polyphenylene sulfide, polyarylate, polyimide, polycarbonate, and/or cellulose acetate propionate. The substrate 100 may have a multilayer structure including two layers including polymer resin and an inorganic layer arranged between the two layers. Alternatively, the substrate 100 may have a structure in which layers including polymer resin and inorganic layers are alternately stacked. The inorganic layer may include, for example, silicon oxide, silicon nitride, or silicon oxynitride.

Sub-pixels may be arranged in the display area DA, and the display area DA may provide an image by using light emitted from the sub-pixels. Each of the sub-pixels may include a light-emitting diode LED, and the light-emitting diode LED may be electrically connected to a sub-pixel circuit PC. The sub-pixel circuit PC and the light-emitting diode LED may be arranged in the display area DA. For convenience, FIG. 9 illustrates that the sub-pixel circuit PC and the light-emitting diode LED are arranged side by side, but in practice, the sub-pixel circuit PC and the light-emitting diode LED may at least partially overlap each other. For example, the light-emitting diode LED may be arranged on the sub-pixel circuit PC.

A gate-driving circuit, a pad 14, a first power supply wiring 15, and a second power supply wiring 16 may be arranged in the peripheral area PA. The gate-driving circuit may include, for example, a first scan-driving circuit 11, a second scan-driving circuit 12, and/or an emission control-driving circuit 13.

The first scan-driving circuit 11 may be configured to provide a scan signal to the sub-pixel circuit PC via a scan line SL. The second scan-driving circuit 12 may be arranged at an opposite side to the first scan-driving circuit 11 with the display area DA therebetween. Some of the sub-pixel circuits PC arranged in the display area DA may be electrically connected to the first scan-driving circuit 11, while the others may be connected to the second scan-driving circuit 12. In some cases, the second scan-driving circuit 12 may be omitted.

Similar to the first scan-driving circuit 11, the emission control-driving circuit 13 may be arranged on one side of the display area DA. The emission control-driving circuit 13 may be configured to provide an emission control signal to a sub-pixel via an emission control line EL. FIG. 9 illustrates that the emission control-driving circuit 13 is arranged on one side of the display area DA, but the disclosure is not limited thereto. For example, the display panel 10 may include emission control-driving circuits 13 arranged on one side and the other side of the display area DA. Alternatively, the first scan-driving circuit 11 may be arranged on one side of the display area DA, and the emission control-driving circuit 13 may be arranged on the other side of the display area DA.

The pad 14 may be arranged in the second peripheral area PA2 of the substrate 100. The pad 14 may be exposed without being covered by an insulating layer and may be electrically connected to the display circuit board 30. A pad 34 of the display circuit board 30 may be electrically connected to the pad 14 of the display panel 10.

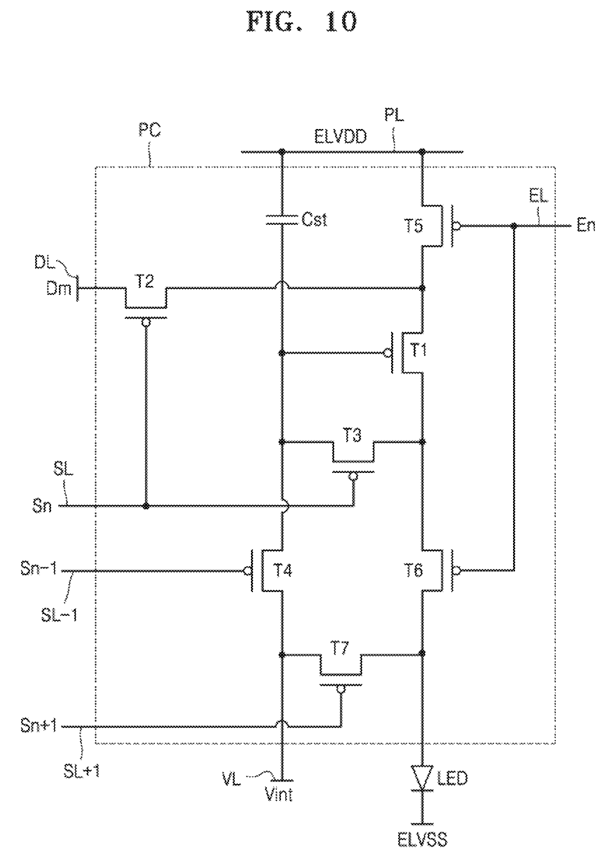

The display circuit board 30 transmits a signal of the controller or power to the display panel 10. A control signal generated by the controller may be transmitted to the gate-driving circuit via the display circuit board 30. In addition, the controller may provide a first power voltage ELVDD (see FIG. 10) and a second power voltage ELVSS (see FIG. 10) to the first power supply wiring 15 and the second power supply wiring 16. The first power voltage ELVDD (referred to as a driving voltage) may be provided to each of the sub-pixel circuits PC via a driving voltage line PL connected to the first power supply wiring 15, and the second power voltage ELVSS (referred to as a common voltage) may be provided to a common electrode of the light-emitting diode LED connected to the second power supply wiring 16. The first power supply wiring 15 may extend in the first direction (the x-axis direction). The second power supply wiring 16 may have a loop shape with one side open and may partially surround the display area DA.

The data signal of the data driver 20 may be transmitted to the sub-pixel circuit PC via a data line DL electrically connected to an input line IL.

FIG. 10 is an equivalent circuit diagram of one sub-pixel arranged in a display area of a display panel of FIG. 8A.

Referring to FIG. 10, the light-emitting diode LED may be electrically connected to the sub-pixel circuit PC.

The sub-pixel circuit PC may include a first thin-film transistor T1, a second thin-film transistor T2, a third thin-film transistor T3, a fourth thin-film transistor T4, a fifth thin-film transistor T5, a sixth thin-film transistor T6, a seventh thin-film transistor T7, and a storage capacitor Cst.

The second thin-film transistor T2, as a switching thin-film transistor, is connected to a scan line SL and the data line DL, and may be configured to transmit, to the first thin-film transistor T1, a data voltage (or a data signal) Dm input from the data line DL based on a switching voltage (or a scan signal) Sn input from the scan line SL. The storage capacitor Cst is connected to the first thin-film transistor T1 and the driving voltage line PL, and may be configured to store a voltage corresponding to a difference between a voltage received from the first thin-film transistor T1 and the first power voltage ELVDD supplied to the driving voltage line PL.

The first thin-film transistor T1, as a driving thin-film transistor, is connected to the driving voltage line PL and the storage capacitor Cst, and may be configured to control a driving current flowing from the driving voltage line PL to the light-emitting diode LED according to a voltage value stored in the storage capacitor Cst. The light-emitting diode LED may emit light having a certain luminance according to the driving current. A second electrode (for example, a cathode) of the light-emitting diode LED may receive the second power voltage ELVSS.

The third thin-film transistor T3 is a compensation thin-film transistor, and a gate electrode of the third thin-film transistor T3 may be connected to the scan line SL. A source electrode (or a drain electrode) of the third thin-film transistor T3 may be connected to a drain electrode (or a source electrode) of the first thin-film transistor T1 and concurrently connected to a first electrode of the light-emitting diode LED via the sixth thin-film transistor T6. The drain electrode (or the source electrode) of the third thin-film transistor T3 may be connected to any one electrode of the storage capacitor Cst, a source electrode (or a drain electrode) of the fourth thin-film transistor T4, and a gate electrode of the first thin-film transistor T1. The third thin-film transistor T3 is turned on according to a scan signal Sn, which is received via the scan line SL, to connect the gate electrode and the drain electrode of the first thin-film transistor T1 to each other, thereby making the first thin-film transistor T1 a diode-connected transistor.

The fourth thin-film transistor T4 is an initialization thin-film transistor, and a gate electrode thereof may be connected to a previous scan line SL-1. The drain electrode (or the source electrode) of the fourth thin-film transistor T4 may be connected to an initialization voltage line VL. The source electrode (or the drain electrode) of the fourth thin-film transistor T4 may be connected to any one electrode of the storage capacitor Cst, the drain electrode (or the source electrode) of the third thin-film transistor T3, and the gate electrode of the first thin-film transistor T1. The fourth thin-film transistor T4 may be turned on according to a previous scan signal Sn-1 received via the previous scan line SL-1 to transmit an initialization voltage Vint to the gate electrode of the first thin-film transistor T1 and perform an initialization operation of initializing a voltage of the gate electrode of the first thin-film transistor T1.

The fifth thin-film transistor T5 is an operation control thin-film transistor and a gate electrode thereof may be connected to the emission control line EL. A source electrode (or a drain electrode) of the fifth thin-film transistor T5 may be connected to the driving voltage line PL. The drain electrode (or the source electrode) of the fifth thin-film transistor T5 is connected to the source electrode (or the drain electrode) of the first thin-film transistor T1 and a drain electrode (or a source electrode) of the second thin-film transistor T2.

The sixth thin-film transistor T6 is an emission control thin-film transistor and a gate electrode thereof may be connected to the emission control line EL. A source electrode (or a drain electrode) of the sixth thin-film transistor T6 may be connected to the drain electrode (or the source electrode) of the first thin-film transistor T1 and the source electrode (or the drain electrode) of the third thin-film transistor T3. The drain electrode (or the source electrode) of the sixth thin-film transistor T6 may be electrically connected to the first electrode of the light-emitting diode LED. The fifth thin-film transistor T5 and the sixth thin-film transistor T6 is turned on at the same time according to an emission control signal En received via the emission control line EL, such that the first power voltage ELVDD is transmitted to the light-emitting diode LED, and a driving current flows through the light-emitting diode LED.

The seventh thin-film transistor T7 may be an initialization thin-film transistor configured to initialize the first electrode of the light-emitting diode LED. A gate electrode of the seventh thin-film transistor T7 may be connected to a subsequent scan line SL+1. A source electrode (or a drain electrode) of the seventh thin-film transistor T7 may be connected to the first electrode of the light-emitting diode LED. The drain electrode (or the source electrode) of the seventh thin-film transistor T7 may be connected to the initialization voltage line VL. The seventh thin-film transistor T7 may be turned on according to a subsequent scan signal Sn+1 received via the subsequent scan line SL+1 to initialize the first electrode of the light-emitting diode LED.

FIG. 10 illustrates a case where the fourth thin-film transistor T4 and the seventh thin-film transistor T7 may be respectively connected to the previous scan line SL-1 and the subsequent scan line SL+1, but in one or more other embodiments, both the fourth thin-film transistor T4 and the seventh thin-film transistor T7 may be connected to the previous scan line SL-1 and driven according to the previous scan signal Sn-1.

The other electrode of the storage capacitor Cst may be connected to the driving voltage line PL. Any one electrode of the storage capacitor Cst may be connected to the gate electrode of the first thin-film transistor T1, the drain electrode (or the source electrode) of the third thin-film transistor T3, and the source electrode (or the drain electrode) of the fourth thin-film transistor T4.

The second electrode (for example, a cathode) of the light-emitting diode LED receives the second power voltage ELVSS. The light-emitting diode LED receives a driving current from the first thin-film transistor T1 and emits light.

The light-emitting diode LED may be an organic light-emitting diode including an organic material as a light-emitting material. In one or more other embodiments, the light-emitting diode LED may be an inorganic light-emitting diode including an inorganic material. The inorganic light-emitting diode may include a PN junction diode including inorganic semiconductor-based materials. When a voltage is applied to a PN junction diode in a forward direction, holes and electrons are injected, and energy generated due to recombination of the holes and the electrons is converted into light energy to emit light of a certain color. The inorganic light-emitting diode may have a width of several to hundreds of micrometers, or several to hundreds of nanometers. In some embodiments, the light-emitting diode LED may include a quantum dot light-emitting diode. As described above, an emission layer of the light-emitting diode LED may include an organic material, inorganic material, a quantum dot, both an organic material and a quantum dot, or both an inorganic material and a quantum dot. Hereinafter, for convenience of explanation, a case where the light-emitting diode LED includes an organic light-emitting diode is described.

FIG. 10 illustrates that the sub-pixel circuit PC includes seven transistors and one capacitor, but in one or more other embodiments, the sub-pixel circuit PC may include two to six or eight or more transistors and two or more capacitors. In addition, a circuit design of the sub-pixel circuit PC is not limited to that shown in FIG. 10 and may be modified in various ways.

The first to seventh thin-film transistors T1, T2, T3, T4, T5, T6, and T7 may be transistors of various types. In one or more embodiments, as shown in FIG. 10, the first to seventh thin-film transistors T1, T2, T3, T4, T5, T6, and T7 may each be a P-channel metal-oxide-semiconductor field effect transistor (MOSFET) (PMOS). In one or more other embodiments, at least one of the first to seventh thin-film transistors T1, T2, T3, T4, T5, T6, or T7 may be a PMOS, while the others may each be an N-channel MOSFET (NMOS). In one or more other embodiments, the first to seventh thin-film transistors T1, T2, T3, T4, T5, T6, and T7 may each be an NMOS. Positions of sources and drains may be swapped depending on the type (a p-type or an n-type) of transistor.

The first to seventh thin-film transistors T1, T2, T3, T4, T5, T6, and T7 shown in FIG. 10 may each be a transistor having a low-temperature polycrystalline silicon (LTPS) semiconductor layer. In this case, the first to seventh thin-film transistors T1, T2, T3, T4, T5, T6, and T7 are not limited to the above, wherein at least one of the first to seventh thin-film transistors T1, T2, T3, T4, T5, T6, or T7 may be a transistor having an LTPS semiconductor layer, and the others may each be a transistor having an oxide semiconductor layer. Alternatively, the first to seventh thin-film transistors T1, T2, T3, T4, T5, T6, and T7 may each be a transistor having an oxide semiconductor layer.

FIG. 11 is a cross-sectional view schematically illustrating a portion of the display area of the display panel of FIG. 8A. FIG. 11 is a cross-sectional view taken along a line B-B' of FIG. 9.

Referring to FIG. 11, the sub-pixel circuit PC (see FIG. 9) and a light-emitting diode, for example, an organic light-emitting diode OLED, arranged in the display area DA of the display panel are shown.

The substrate 100 may include glass, ceramic, metal, or polymer resin. In one or more embodiments, the substrate 100 may have a structure in which a base layer including polymer resin and a barrier layer including an inorganic insulating material, such as silicon oxide or silicon nitride are alternately stacked. When the substrate 100 includes a structure of a stack of a base layer including polymer resin and a barrier layer including an inorganic insulating material, the flexibility of the electronic apparatus 1 (see FIGS. 5 to 7) is improved, and thus, the foldable electronic apparatus 1 may be provided.

The inorganic insulating material may include silicon oxide, silicon nitride, and/or silicon oxynitride.

The substrate 100 may include polymer resin, such as polyethersulfone, polyacrylate, polyetherimide, polyethylene naphthalate, polyethylene terephthalate, polyphenylene sulfide, polyarylate, polyimide, polycarbonate, and/or cellulose acetate propionate. Hereinafter, for convenience of explanation, a case where the substrate 100 includes a glass material is described in detail.

The sub-pixel circuit PC may be formed on the substrate 100, and the light-emitting diode, for example, the organic light-emitting diode OLED, may be formed on the sub-pixel circuit PC.

Before the sub-pixel circuit PC is formed on the substrate 100, a buffer layer 201, which is formed to reduce or prevent penetration of impurities into the sub-pixel circuit PC, may be formed on the substrate 100. The buffer layer 201 may include an inorganic insulating material, such as silicon nitride, silicon oxynitride, and/or silicon oxide, and may have a single-layered or multilayer structure including the inorganic insulating material.

The sub-pixel circuit PC may include a plurality of transistors and a storage capacitor Cst, as described above with reference to FIG. 10. In this regard, FIG. 11 illustrates the first thin-film transistor T1, the third thin-film transistor T3, and the storage capacitor Cst.

The first thin-film transistor T1 may include a semiconductor layer (hereinafter, referred to as a first semiconductor layer) A1 on the buffer layer 201 and a gate electrode (hereinafter, referred to as a first gate electrode) GE1 overlapping a channel area C1 of the first semiconductor layer A1. The first semiconductor layer A1 may include a silicon-based semiconductor material, for example, polysilicon. The first semiconductor layer A1 may include the channel area C1, and a first area B1 and a second area D1 respectively arranged at opposite sides of the channel area C1. The first area B1 and the second area D1 include a higher concentration of impurities than the channel area C1, wherein any one of the first area B1 or the second area D1 may correspond to a source area, while the other one may correspond to a drain area.

A first gate-insulating layer 203 may be arranged between the first semiconductor layer A1 and the first gate electrode GE1. The first gate-insulating layer 203 may include an inorganic insulating material, such as silicon oxide, silicon nitride, and/or silicon oxynitride, and may have a single-layered or multilayer structure including the inorganic insulating material.

The first gate electrode GE1 may include a conductive material including molybdenum (Mo), aluminum (Al), copper (Cu), or titanium (Ti), and may have a single-layered or multilayer structure including the above-described material.

The storage capacitor Cst may include a lower electrode CE1 and an upper electrode CE2, which overlap each other. In one or more embodiments, the lower electrode CE1 of the storage capacitor Cst may include the first gate electrode GE1. In other words, the first gate electrode GE1 may include the lower electrode CE1 of the storage capacitor Cst. For example, the first gate electrode GE1 and the lower electrode CE1 of the storage capacitor Cst may be integrally formed as a single body.

A first interlayer insulating layer 205 may be arranged between the lower electrode CE1 and the upper electrode CE2 of the storage capacitor Cst. The first interlayer insulating layer 205 may include an inorganic insulating material, such as silicon oxide, silicon nitride, or silicon oxynitride, and may have a single-layered or multilayer structure including the inorganic insulating material.

The upper electrode CE2 of the storage capacitor Cst may include a low-resistance conductive material, such as molybdenum (Mo), aluminum (Al), copper (Cu), and/or titanium (Ti), and may have a single-layered or multilayer structure including the above-described material.

A second interlayer insulating layer 207 may be arranged on the storage capacitor Cst. The second interlayer insulating layer 207 may include an inorganic insulating material, such as silicon oxide, silicon nitride, or silicon oxynitride, and may have a single-layered or multilayer structure including the inorganic insulating material.

A semiconductor layer (hereinafter, referred to as a third semiconductor layer) A3 of the third thin-film transistor T3 may be arranged on the second interlayer insulating layer 207. The third semiconductor layer A3 may include a silicon-based semiconductor material, for example, polysilicon.

The third semiconductor layer A3 may include a channel area C3, and a first area B3 and a second area D3 arranged at opposite sides of the channel area C3. Any one of the first area B3 or the second area D3 may correspond to a source area, and the other one may correspond to a drain area.

The third thin-film transistor T3 may include a gate electrode (hereinafter, referred to as a third gate electrode) GE3 overlapping the channel area C3 of the third thin-film transistor T3. The third gate electrode GE3 may have a dual gate structure including a lower gate electrode G3A arranged under the third semiconductor layer A3 and an upper gate electrode G3B arranged above the channel area C3.

The lower gate electrode G3A may be arranged on the same layer (for example, the first interlayer insulating layer 205) as the upper electrode CE2 of the storage capacitor Cst. The lower gate electrode G3A may include the same material as the upper electrode CE2 of the storage capacitor Cst.

The upper gate electrode G3B may be arranged above the third semiconductor layer A3 with a second gate-insulating layer 209 therebetween. The second gate-insulating layer 209 may include an inorganic insulating material, such as silicon oxide, silicon nitride, or silicon oxynitride, and may have a single-layered or multilayer structure including the inorganic insulating material.

A third interlayer insulating layer 210 may be arranged on the upper gate electrode G3B. The third interlayer insulating layer 210 may include an inorganic insulating material, such as silicon oxynitride, and may have a single-layered or multilayer structure including the inorganic insulating material.

FIG. 11 illustrates the first thin-film transistor T1 and the third thin-film transistor T3 among a plurality of thin-film transistors as described with reference to FIG. 10, and illustrates that the first semiconductor layer A1 and the third semiconductor layer A3 are arranged on different layers, but the disclosure is not limited thereto.

The second, fourth, fifth, sixth, and seventh thin-film transistors T2, T4, T5, T6, and T7 described with reference to FIG. 10 may each have the same structure as the first thin-film transistor T1 described with reference to FIG. 11. For example, the second, fourth, fifth, sixth, and seventh thin-film transistors T2, T4, T5, T6, and T7 may each include a semiconductor layer arranged on the same layer as the first semiconductor layer A1 of the first thin-film transistor T1, and a gate electrode arranged on the same layer as the first gate electrode GE1 of the first thin-film transistor T1. The semiconductor layers of the second, fourth, fifth, sixth, and seventh thin-film transistors T2, T4, T5, T6, and T7 may be integrally connected to the first semiconductor layer A1.

The first thin-film transistor T1 and the third thin-film transistor T3 may be electrically connected to each other via a node connection line 166. The node connection line 166 may be arranged on the third interlayer insulating layer 210. One side of the node connection line 166 may be connected to the first gate electrode GE1 of the first thin-film transistor T1, and the other side of the node connection line 166 may be connected to the third semiconductor layer A3 of the third thin-film transistor T3.

The node connection line 166 may include aluminum (Al), copper (Cu), and/or titanium (Ti), and may be formed as a single layer or a multilayer, each including the above-described material. For example, the node connection line 166 may have a three-layer structure of titanium layer/aluminum layer/titanium layer.

A first organic insulating layer 211 may be arranged on the node connection line 166. The first organic insulating layer 211 may include an organic insulating material. The organic insulating material may include acryl, benzocyclobutene (BCB), polyimide, or hexamethyldisiloxane (HMDSO).

The data line DL and the driving voltage line PL may be arranged on the first organic insulating layer 211, and may be covered with a second organic insulating layer 213. The data line DL and the driving voltage line PL may each include aluminum (Al), copper (Cu), and/or titanium (Ti), and may each be formed as a single layer or a multilayer, each including the above-described material. For example, the data line DL and the driving voltage line PL may have a three-layer structure of titanium layer/aluminum layer/titanium layer.

The second organic insulating layer 213 may include an organic insulating material, such as acryl, BCB, polyimide, and/or HMDSO. FIG. 11 illustrates that the data line DL and the driving voltage line PL are formed on the first organic insulating layer 211, but the disclosure is not limited thereto. In one or more other embodiments, any one of the data line DL or the driving voltage line PL may be arranged on the same layer, for example, the third interlayer insulating layer 210, as the node connection line 166.

The light-emitting diode, for example, the organic light-emitting diode OLED, may be arranged on the second organic insulating layer 213.

A first electrode 221 of the organic light-emitting diode OLED may include a reflective film including silver (Ag), magnesium (Mg), aluminum (Al), platinum (Pt), palladium (Pd), gold (Au), nickel (Ni), neodymium (Nd), iridium (Ir), chromium (Cr), and/or compounds thereof. In one or more other embodiments, the first electrode 221 may further include a conductive oxide layer arranged above and/or under the reflective film. The conductive oxide layer may include indium tin oxide (ITO), indium zinc oxide (IZO), zinc oxide (ZnO), indium oxide (In₂O₃), indium gallium oxide (IGO), and/or aluminum zinc oxide (AZO). In one or more embodiments, the first electrode 221 may have a three-layer structure of ITO layer/Ag layer/ITO layer.

A bank layer 215 may be arranged on the first electrode 221. The bank layer 215 may include, or define, an opening overlapping the first electrode 221 and cover an edge of the first electrode 221. The bank layer 215 may include an organic insulating material, such as polyimide.

An intermediate layer 222 includes an emission layer 222b. The intermediate layer 222 may include a first functional layer 222a arranged under the emission layer 222b and/or a second functional layer 222c arranged above the emission layer 222b. The emission layer 222b may include a polymer or low-molecular-weight organic material that emits light of a certain color. The second functional layer 222c may include an electron transport layer (ETL) and/or an electron injection layer (EIL). The first functional layer 222a and the second functional layer 222c may include an organic material.

A second electrode 223 may include a conductive material having a low work function. For example, the second electrode 223 may include a (semi-)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), and/or an alloy thereof. Alternatively, the second electrode 223 may further include a layer including ITO, IZO, ZnO, and/or In₂O₃ on the (semi-)transparent layer including the above-described material.

The emission layer 222b may be formed on the display area DA to overlap the first electrode 221 via the opening in the bank layer 215. In contrast, the first functional layer 222a, the second functional layer 222c, and the second electrode 223 may entirely cover the display area DA.

A spacer 217 may be formed on the bank layer 215. The spacer 217 and the bank layer 215 may be formed together in the same process or may be formed individually in separate processes. In one or more embodiments, the spacer 217 may include an organic insulating material, such as polyimide. Alternatively, the bank layer 215 may include an organic insulating material including a light-blocking dye, and a spacer 217 may include an organic insulating material, such as polyimide.

The organic light-emitting diode OLED may be covered with an encapsulation layer 300. The encapsulation layer 300 may include at least one organic encapsulation layer and at least one inorganic encapsulation layer. In one or more embodiments, FIG. 11 illustrates that the encapsulation layer 300 includes first and second inorganic encapsulation layers 310 and 330 and an organic encapsulation layer 320 arranged therebetween.

The first inorganic encapsulation layer 310 and the second inorganic encapsulation layer 330 may include one or more inorganic materials among aluminum oxide, titanium oxide, tantalum oxide, hafnium oxide, zinc oxide (ZnOₓ, may be ZnO or ZnO₂), silicon oxide, silicon nitride, and silicon oxynitride. The first inorganic encapsulation layer 310 and the second inorganic encapsulation layer 330 may each be a single layer or a multilayer, each including the above-described material. The organic encapsulation layer 320 may include a polymer-based material. The polymer-based material may include acrylic-based resin, epoxy-based resin, polyimide, and polyethylene. In one or more embodiments, the organic encapsulation layer 320 may include acrylate.

The thicknesses of the first inorganic encapsulation layer 310 and the second inorganic encapsulation layer 330 may be different from each other. The thickness of the first inorganic encapsulation layer 310 may be greater than the thickness of the second inorganic encapsulation layer 330. Alternatively, the thickness of the second inorganic encapsulation layer 330 may be greater than the thickness of the first inorganic encapsulation layer 310, or the thicknesses of the first inorganic encapsulation layer 310 and the second inorganic encapsulation layer 330 may be identical to each other.

An input-sensing layer 400 may be arranged on the encapsulation layer 300. The input-sensing layer 400 may include touch electrodes TE arranged in the display area DA and at least one touch insulating layer. In this regard, FIG. 11 illustrates that the input-sensing layer 400 includes a first touch insulating layer 410 on the second inorganic encapsulation layer 330, a first conductive line 420 on the first touch insulating layer 410, a second touch insulating layer 430 on the first conductive line 420, a second conductive line 440 on the second touch insulating layer 430, and a third touch insulating layer 450 on the second conductive line 440.

Each of the first touch insulating layer 410, the second touch insulating layer 430, and the third touch insulating layer 450 may include an inorganic insulating material and/or an organic insulating material. In one or more embodiments, the first touch insulating layer 410 and the second touch insulating layer 430 may each include an inorganic insulating material, such as silicon oxide, silicon nitride, and/or silicon oxynitride, and the third touch insulating layer 450 may include an organic insulating material.

A touch electrode TE of the input-sensing layer 400 may include a structure in which the first conductive line 420 and the second conductive line 440 are connected. Alternatively, the touch electrode TE may include any one of the first conductive line 420 or the second conductive line 440, and in this case, the second touch insulating layer 430 may be omitted.

Each of the first conductive line 420 and the second conductive line 440 may include aluminum (Al), copper (Cu), and/or titanium (Ti), and may be formed as a single layer or a multilayer, each including the above-described material. For example, each of the first conductive line 420 and the second conductive line 440 may have a three-layer structure of titanium layer/aluminum layer/titanium layer.

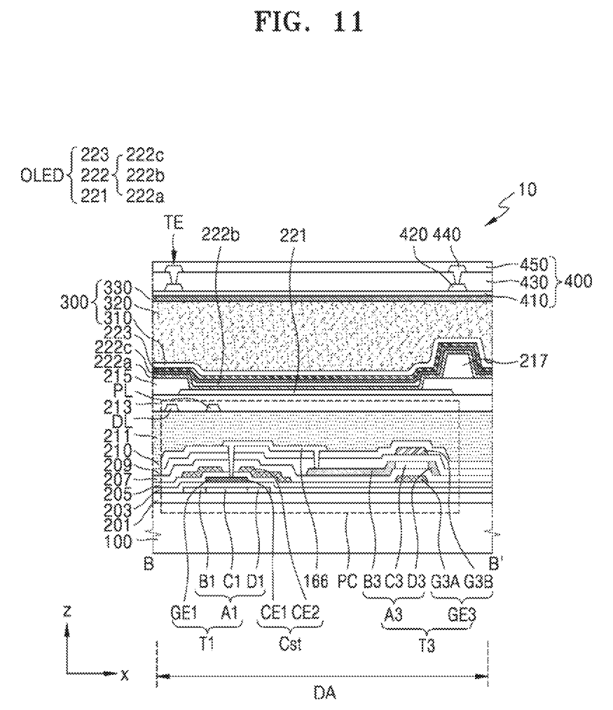

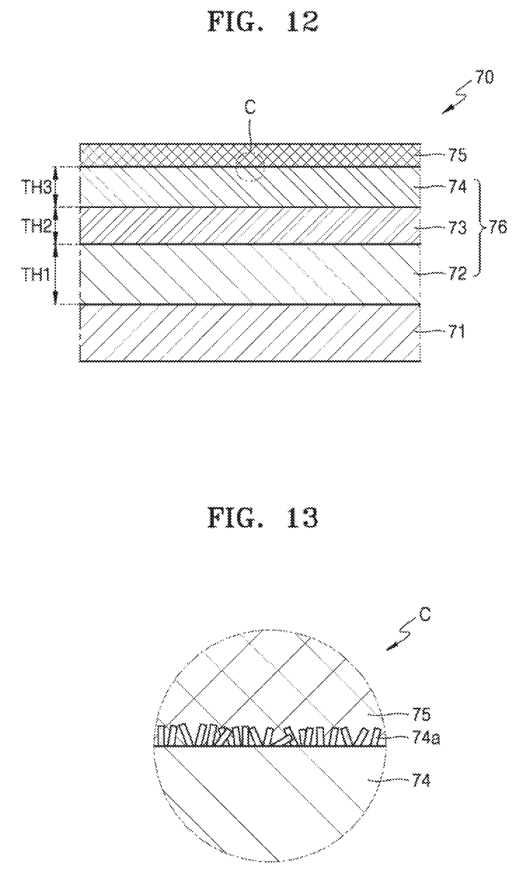

FIG. 12 is a cross-sectional view schematically illustrating a cover member according to one or more embodiments. FIG. 13 is an enlarged cross-sectional view of a portion C of FIG. 12.

Referring to FIGS. 12 and 13, the cover member 70 may include a base layer 71, a coating layer 76, and an anti-fingerprint layer 75. The cover member 70 may further include at least one micro-protrusion on one surface in contact with the anti-fingerprint layer 75.

The base layer 71 may include a transparent material. For example, the base layer 71 may include glass, polyimide, and/or plastic.

The coating layer 76 may include a first layer 72, which is a lower layer, a second layer 73, which is an intermediate layer, and a third layer 74, which is an upper layer.

The first layer 72 may be arranged directly on the base layer 71. In this case, the first layer 72 may include aluminum oxide (Al₂O₃). The refractive index of the first layer 72 may be within a range of at least about 1.57 and not more than about 1.73. In addition, a first thickness TH1 of the first layer 72 may have a range of at least about 80 nm and not more than about 123 nm. In this case, the first layer 72 may be formed on the base layer 71 by using an E-beam deposition method or a sputtering method, by which a deposition material is vaporized and arranged on the base layer 71. In a case as described above, the first layer 72 may be arranged on an entire surface of the base layer 71. In a case as described above, when the first thickness TH1 is less than 80 nm, the average reflectance of the entire coating layer 76 is too low, and thus, foreign substances and/or scratches on the base layer 71 may be visible. In addition, when the first thickness TH1 is greater than 123 nm, a color difference may occur in an image implemented on a display panel, and thus, the image implemented on the display panel may not be clear. When the refractive index of the first layer 72 is greater than 1.73, the visibility of foreign substances and/or scratches on the base layer 71 may increase, and when the refractive index of the first layer 72 is less than 1.57, an image implemented on a display panel may not be clear.

The second layer 73 may be arranged on the first layer 72. In this case, the second layer 73 may include titanium oxide (TiO₂). The refractive index of the second layer 73 may be within a range of at least about 2.1 and not more than about 2.42. In addition, a second thickness TH2 of the second layer 73 may have a range of at least about 70 nm and not more than about 98 nm. In this case, the second layer 73 may be formed on the base layer 71 by using an E-beam deposition method or a sputtering method, by which a deposition material is vaporized and arranged on the first layer 72. In a case as described above, the second layer 73 may be arranged on an entire surface of the first layer 72. In a case as described above, when the second thickness TH2 is less than 70 nm, the average reflectance of the entire coating layer 76 is too low, and thus, foreign substances and/or scratches on the base layer 71 may be visible. In addition, when the second thickness TH2 is greater than 98 nm, a color difference may occur in an image implemented on a display panel, and thus, the image implemented on the display panel may not be clear. When the refractive index of the second layer 73 is greater than 2.42, the visibility of foreign substances and/or scratches on the base layer 71 may increase, and when the refractive index of the second layer 73 is less than 2.1, an image implemented on a display panel may not be clear.

The third layer 74 may be arranged on the second layer 73. In this case, the third layer 74 may include silicon oxide (SiO₂). The refractive index of the third layer 74 may be within a range of at least about 1.41 and not more than about 1.56. In addition, a third thickness TH3 of the third layer 74 may have a range of at least about 68 nm and not more than about 90 nm. In this case, the third layer 74 may be arranged and formed on the second layer 73 by using an E-beam deposition method. In a case as described above, the third layer 74 may be arranged on an entire surface of the second layer 73. In a case as described above, when the third thickness TH3 is less than 68 nm, the average reflectance of the entire coating layer 76 is too low, and thus, foreign substances and/or scratches on the base layer 71 may be visible. In addition, when the third thickness TH3 is greater than 90 nm, a color difference may occur in an image implemented on a display panel, and thus, the image implemented on the display panel may not be clear. When the refractive index of the third layer 74 is greater than 1.56, the visibility of foreign substances and/or scratches on the base layer 71 may increase, and when the refractive index of the third layer 74 is less than 1.41, an image implemented on a display panel may not be clear.

The third layer 74 may include at least one micro-protrusion 74a. It is understood that at least one micro-protrusion 74a disposed on the third layer 74. In this case, a micro-protrusion 74a may include a plurality of micro-protrusions 74a, and the plurality of micro-protrusions 74a may be arranged in a disorderly manner so as to intersect with, be parallel to, and/or not be parallel to each other. The micro-protrusion 74a may have a shape protruding from a flat surface of the third layer 74, and the micro-protrusion 74a may have a pillar shape. An end portion of the micro-protrusion 74a may have various shapes. In one or more embodiments, the end portion of the micro-protrusion 74a may be flat as shown in FIG. 13. In one or more other embodiments, the end portion of the micro-protrusion 74a may not be flat as shown in FIG. 13. For example, in one or more embodiments, the end portion of the micro-protrusion 74a may be pointed in a similar way to the tip of a needle. In one or more other embodiments, the end portion of the micro-protrusion 74a may be a rounded curved surface. In one or more other embodiments, the end portion of the micro-protrusion 74a may include at least one protrusion that is smaller than the micro-protrusion 74a. However, hereinafter, for convenience of explanation, a case where the end portion of the micro-protrusion 74a is flat as shown in FIG. 13 is described in detail. The length of the micro-protrusion 74a may be within a range of 30 nm or less. When the length of the micro-protrusion 74a is greater than 30 nm, the efficiency of external light reflection by the micro-protrusion 74a may rapidly decrease, leading to a decrease in the average reflectance of the third layer 74. The surface roughness of the third layer 74 including the micro-protrusion 74a may have a range of at least about 1.9 µm and not more than about 2.5 µm. In this case, the surface roughness may mean root-mean-square (rms) roughness.

In a case as described above, the micro-protrusion 74a may cause diffuse reflection on a surface of the third layer 74. Accordingly, the micro-protrusion 74a may reflect external light.

The coating layer 76 including the first layer 72, the second layer 73, and the third layer 74 may have an average reflectance of at least about 8.5% and not more than about 12% within a wavelength range of at least about 520 nm and not more than about 580 nm. In addition, the coating layer 76 may have an average transmittance of at least about 88% and not more than about 91.5% within a wavelength range of at least about 520 nm and not more than about 580 nm. When the average reflectance of the coating layer 76 is greater than 12% or the average transmittance of the coating layer 76 is less than 88%, an image on a display panel may appear blurry on a top surface of the cover member 70. In contrast, when the average reflectance of the coating layer 76 is less than 8.5% or the average transmittance of the coating layer 76 is greater than 91.5%, a portion of external light, in a visible light range, incident on an electronic apparatus is transmitted, and thus, glare caused by foreign substances or scratches on the base layer 71 may be visible. In this case, an image implemented on a display panel may not be clearly visible, and it may also be mistaken for a defect on the base layer 71.

The anti-fingerprint layer 75 may be arranged on the third layer 74. In this case, the anti-fingerprint layer 75 may include a fluorine-based silane material. For example, the anti-fingerprint layer 75 may be in the form of a fluorine-based silane coating based on perfluoropolyether (PFPE) resin. The thickness of the anti-fingerprint layer 75 may be within a range of at least about 10 nm and not more than about 40 nm. The anti-fingerprint layer 75 may be arranged on an outermost portion of the cover member 70 to reduce the presence of a user's fingerprint. The refractive index of the anti-fingerprint layer 75 may be less than the refractive index of the third layer 74.

In a case as described above, a display apparatus and an electronic apparatus may not only reduce the visibility of damage to the cover member 70 caused by external light, but also enable an image implemented on the display apparatus or the electronic apparatus to be clearly visible.

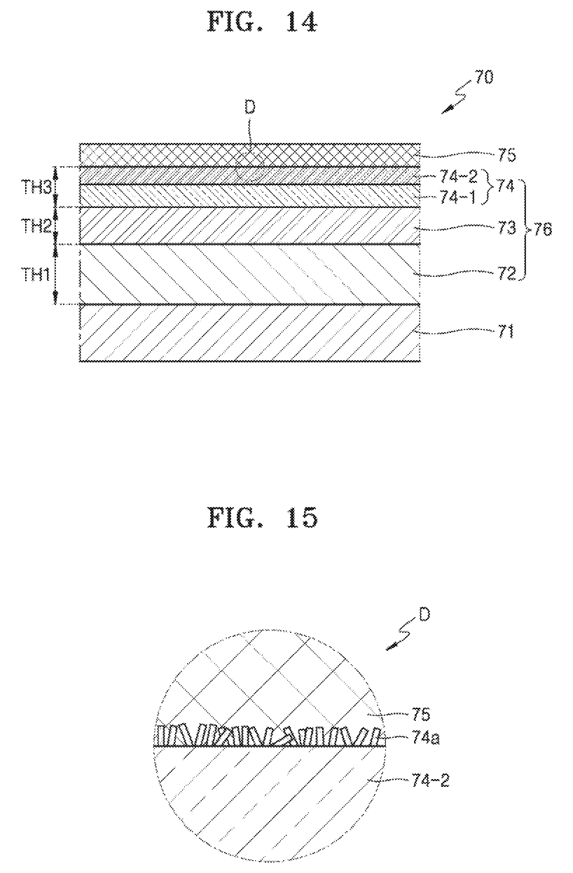

FIG. 14 is a cross-sectional view schematically illustrating a cover member according to one or more other embodiments. FIG. 15 is an enlarged cross-sectional view of a portion D of FIG. 14.

Referring to FIGS. 14 and 15, the cover member 70 may include the base layer 71, the coating layer 76, and the anti-fingerprint layer 75. The coating layer 76 may include the first layer 72, the second layer 73, and the third layer 74. In this case, the base layer 71, the first layer 72, the second layer 73, and the anti-fingerprint layer 75 may be the same as or similar to those described with reference to FIGS. 12 and 13. In addition, the first thickness TH1 and refractive index of the first layer 72, the second thickness TH2 and refractive index of the second layer 73, and the third thickness TH3 and refractive index of the third layer 74 may be the same as or similar to those described with reference to FIGS. 12 and 13.

The third layer 74 may include a third-1 layer 74-1, which is formed on the second layer 73 by using a sputtering method, and a third-2 layer 74-2, which is formed on the third-1 layer 74-1 by using an E-beam deposition method. In this case, the third-1 layer 74-1 may have a plate shape, and an area in which the third-1 layer 74-1 is in contact with the third-2 layer 74-2 may be flat. The third-2 layer 74-2 may include the micro-protrusion 74a on a top surface thereof. The micro-protrusion 74a may not only increase the bonding strength of the coating layer 76 and the anti-fingerprint layer 75, but also may increase the average reflectance of the coating layer 76 by diffusely reflecting external light. In this case, the end portion of the micro-protrusion 74a may have various shapes as described with reference to FIGS. 12 and 13.

The cover member, the display apparatus, and the electronic apparatus according to embodiments may effectively reflect external light.

The cover member, the display apparatus, and the electronic apparatus according to the present disclosure may increase the visibility of an image on a display panel.

It should be understood that embodiments described herein should be considered in a descriptive sense only and not for purposes of limitation. Descriptions of aspects within the embodiments should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, with functional equivalents thereof to be included therein.

What is claimed is:

1. A display apparatus comprising:
a display panel; and
a cover member comprising:
a base layer above the display panel;
a coating layer above the base layer;
an anti-fingerprint layer above the coating layer; and
at least one micro-protrusion on one surface in contact with the anti-fingerprint layer.

2. The display apparatus of claim 1, wherein the coating layer comprises:
a lower layer above the base layer;
an intermediate layer above the lower layer; and
an upper layer above the intermediate layer,
wherein the upper layer, the intermediate layer, and the lower layer comprise different respective materials.

3. The display apparatus of claim 2, wherein a refractive index of one of the lower layer, the intermediate layer, or the upper layer is different from a refractive index of another one of the lower layer, the intermediate layer, or the upper layer.

4. The display apparatus of claim 2, wherein a refractive index of the lower layer is more than about 1.57 and less than about 1.73, and/or
wherein a thickness of the lower layer is more than about 80 nm and less than about 123 nm, and/or
wherein a refractive index of the intermediate layer is more than about 2.1 and less than about 2.42, and/or
wherein a thickness of the intermediate layer is more than about 70 nm and less than about 98 nm, and/or
wherein a refractive index of the upper layer is more than about 1.41 and less than about 1.56, and/or
wherein a thickness of the upper layer is more than about 68 nm and less than about 90 nm, and/or
wherein a filling rate of the upper layer is more than about 40% and less than about 160%, and/or
wherein the coating layer has an average reflectance of more than about 8.5% and less than about 12% when irradiated with light with a wavelength of more than about 520 nm and less than about 580 nm, and/or
wherein the coating layer has an average transmittance of more than about 88% and less than about 91.5% when irradiated with light with a wavelength of more than about 520 nm and less than about 580 nm, and/or
wherein a thickness of the anti-fingerprint layer is more than about 10 nm and less than about 40 nm.

5. The display apparatus of claim 2, wherein the lower layer comprises aluminum oxide.

6. The display apparatus of claim 2, wherein the intermediate layer comprises titanium oxide.

7. The display apparatus of claim 2, wherein the upper layer comprises silicon dioxide.

8. The display apparatus of claim 2, wherein a refractive index of the upper layer is greater than a refractive index of the anti-fingerprint layer.

9. An electronic apparatus comprising a display apparatus, wherein the display apparatus comprises:
a display panel; and
a cover member comprising:
a base layer above the display panel;
a coating layer above the base layer;
an anti-fingerprint layer above the coating layer; and
at least one micro-protrusion on one surface in contact with the anti-fingerprint layer.

10. The electronic apparatus of claim 9, wherein the coating layer comprises:
a lower layer above the base layer;
an intermediate layer above the lower layer; and
an upper layer above the intermediate layer,
wherein the upper layer, the intermediate layer, and the lower layer comprise different respective materials.

11. The electronic apparatus of claim 10, wherein a refractive index of one of the lower layer, the intermediate layer, or the upper layer is different from a refractive index of another one of the lower layer, the intermediate layer, or the upper layer.

12. The electronic apparatus of claim 10, wherein a refractive index of the lower layer is more than about 1.57 and less than about 1.73, and/or
wherein a refractive index of the intermediate layer is more than about 2.1 and less than about 2.42, and/or
wherein a refractive index of the upper layer is more than about 1.41 and less than about 1.56, and/or
wherein a refractive index of the upper layer is greater than a refractive index of the anti-fingerprint layer.

13. A cover member comprising:
a base layer above a display panel;
a coating layer above the base layer;
an anti-fingerprint layer above the coating layer; and
at least one micro-protrusion on one surface in contact with the anti-fingerprint layer.

14. The cover member of claim 13, wherein the coating layer comprises:
a lower layer above the base layer;
an intermediate layer above the lower layer; and
an upper layer above the intermediate layer,
wherein the upper layer, the intermediate layer, and the lower layer comprise different respective materials.

15. The cover member of claim 14, wherein a refractive index of one of the lower layer, the intermediate layer, or the upper layer is different from a refractive index of another one of the lower layer, the intermediate layer, or the upper layer.

16. The cover member of claim 14, wherein a refractive index of the lower layer is more than about 1.57 and less than about 1.73, and/or
wherein a thickness of the lower layer is more than about 80 nm and less than about 123 nm, and/or
wherein a thickness of the intermediate layer is more than about 70 nm and less than about 98 nm, and/or
wherein a refractive index of the intermediate layer is more than about 2.1 and less than about 2.42, and/or
wherein a filling rate of the upper layer is more than about 40% and less than about 140%, and/or
wherein a refractive index of the upper layer is more than about 1.41 and less than about 1.56, and/or
wherein a thickness of the upper layer is more than about 68 nm and less than about 90 nm, and/or
wherein the coating layer has an average reflectance of more than about 8.5% and less than about 12% when irradiated with light with a wavelength of more than about 520 nm and less than about 580 nm, and/or
wherein the coating layer has an average transmittance of more than about 88% and less than about 91.5% when irradiated with light with a wavelength of more than about 520 nm and less than about 580 nm, and/or
wherein a thickness of the anti-fingerprint layer is more than about 9 nm and less than about 40 nm.

17. The cover member of claim 14, wherein the lower layer comprises aluminum oxide.

18. The cover member of claim 14, wherein the intermediate layer comprises titanium oxide.

19. The cover member of claim 14, wherein the upper layer comprises silicon dioxide.

20. The cover member of claim 14, wherein a refractive index of the upper layer is greater than a refractive index of the anti-fingerprint layer.
